(19) United States
(12) Patent Application Publication
(10) Pub. No.: US 2014/0312450 A1
(43) Pub. Date: Oct. 23, 2014

(54) Small Size, Weight, and Packaging of Image Sensors

(71) Applicant: Sensors Unlimited, Inc., Princeton, NJ (US)

(72) Inventors: John Tagle, Cherry Hill, NJ (US); Dmitry Zhilinsky, Richboro, PA (US); Michael Liland, JR., Marlton, NJ (US)

(73) Assignee: Sensors Unlimited, Inc., Princeton, NJ (US)

(21) Appl. No.: 14/198,923

(22) Filed: Mar. 6, 2014

Related U.S. Application Data
(60) Provisional application No. 61/815,192, filed on Apr. 23, 2013.

(51) Int. Cl. H01L 27/146

(52) U.S. Cl. CPC H01L 27/14687; H01L 27/14643; H01L 27/1469
USPC 257/443; 438/67

(57) ABSTRACT

A method and structure of an image sensor device including a read out integrated circuit (ROIC) and a photodiode array (PDA). An embodiment may include a package substrate having a recess and a raised pedestal within the recess; a read out integrated circuit (ROIC) physically attached to the raised pedestal; a photodiode array (PDA) physically attached to the ROIC and electrically coupled therewith; and a printed circuit board (PCB) within the recess in the package substrate, wherein the PCB has an opening therein and the raised pedestal at least partially extends through the opening in the PCB.

### CROSS-REFERENCE TO RELATED APPLICATIONS

This application claims the benefit of U.S. Provisional Application No. 61/815,192, filed Apr. 23, 2013, the entire contents of which are herein incorporated by reference.

### FIELD OF THE INVENTION

The present teachings relate to the field of integrated circuits and, more particularly, to packaging for a focal plane array device including a photodiode array and a read out integrated circuit.

### BACKGROUND OF THE INVENTION

Light-sensitive image sensors such as focal plane array (FPA) devices include a photodiode array (PDA) packaged with a read out integrated circuit (ROIC). Many different FPA package configurations are available including, for example, leaded and leadless packages. Each conventional package type for FPA can include various shared characteristics.

FIG. 6 depicts a schematic cross-section of an FPA device 200 packaged as a leadless chip carrier (LCC). FIG. 6 includes a ceramic, plastic, or resin carrier body 202 including internal traces 204 electrically coupled to external pads or castellations 206. The external pads 206 can be surface mounted to a circuit board using a conductor, or the device 200 can be placed into an LCC socket. FIG. 6 further depicts a ROIC 208 physically attached to the carrier 202 using an adhesive 210. Bond wires 212 electrically couple bond pads (not individually depicted for simplicity) on the ROIC 208 to the traces 204 within the carrier body 202 such that circuitry on the ROIC 208 can be electrically accessed through the external pads 206. A PDA 214 is mounted to the upper surface of the ROIC 208 using a nonconductive adhesive (not individually depicted for simplicity). Other bond wires 218 electrically couple circuitry on the PDA 214 to circuitry on the ROIC 208. A package lid 216 hermetically sealed to the carrier 202 includes a clear window 216A that exposes the PDA 214 to external light. In the device 200 of FIG. 6, the carrier 202 is configured such that the lower surface of the lid 216 does not contact the loop in the bond wires 212, 218. FPAs including ROICs and PDAs provided in different package styles are well known.

Design goals for semiconductor device engineers include providing devices having smaller dimensions and weight, a reduced cost, and improved reliability. A device design that helped to accomplished one or more these goals would be desirable.

### SUMMARY OF THE INVENTION

The following presents a simplified summary in order to provide a basic understanding of some aspects of one or more embodiments of the present teachings. This summary is not an extensive overview, neither is it intended to identify key or critical elements of the present teachings nor to delineate the scope of the disclosure. Rather, its primary purpose is merely to present one or more concepts in simplified form as a prelude to the detailed description presented later.

In an embodiment, an image sensor may include a package substrate comprising a recess and a raised pedestal within the recess, a read out integrated circuit (ROIC) physically attached to the raised pedestal, a photodiode array (PDA) physically attached to the ROIC and electrically coupled therewith, and a printed circuit board (PCB) within the recess in the package substrate, wherein the PCB has an opening therein and the raised pedestal at least partially extends through the opening in the PCB.

In addition to one or more of the features described above, or as an alternative, further embodiments could include a metal package substrate.

In addition to one or more of the features described above, or as an alternative, further embodiments could include an encapsulation layer that environmentally seals a surface of the PCB within the package substrate.

In addition to one or more of the features described above, or as an alternative, further embodiments could include an electrical connector electrically coupled to the PCB, wherein the electrical connector extends from the circuit board through the encapsulation layer to provide an external package electrical connection to the PCB.

In addition to one or more of the features described above, or as an alternative, further embodiments could include encapsulation layer that is formed on a first side of the package substrate and the device further comprises an electrical connector electrically coupled to the PCB and extending from a second side of the package substrate that is opposite the first side to provide an external package electrical connection to the PCB.

In addition to one or more of the features described above, or as an alternative, further embodiments could include an optically transparent window attached to the PDA, wherein the encapsulation layer physically contacts the optically transparent window.

In addition to one or more of the features described above, or as an alternative, further embodiments could include a plurality of bond wires that electrically couple the PCB to the ROIC.

In addition to one or more of the features described above, or as an alternative, further embodiments could include a PDA that is flip chip mounted to the ROIC and the plurality of bond wires are electrically coupled to the PDA through the ROIC.

In addition to one or more of the features described above, or as an alternative, further embodiments could include that the ROIC, the PDA, and the PCB are received within the recess in the package substrate in their entirety.

In addition to one or more of the features described above, or as an alternative, further embodiments could include a PCB that surrounds the ROIC and the PDA through 360 degrees.

In another embodiment, a method for forming an image sensor may include attaching a printed circuit board (PCB) within a recess in a package substrate such that a raised pedestal within the recess of the package substrate at least partially extends through an opening within the PCB, attaching a read out integrated circuit (ROIC) to the raised pedestal of the package substrate, attaching a photodiode array (PDA) to the ROIC, wherein the PDA is electrically coupled to the ROIC, and electrically coupling the ROIC to the PCB.

In addition to one or more of the features described above, or as an alternative, further embodiments could include attaching of the PCB within the recess of the package substrate attaches the PCB to a metal package substrate.

In addition to one or more of the features described above, or as an alternative, further embodiments could include dispensing an encapsulation layer within the recess in the package substrate to environmentally seal a surface of the PCB within the package substrate.

In addition to one or more of the features described above, or as an alternative, further embodiments could include physically contacting an electrical connector with the encapsulation layer during the dispensing of the encapsulation layer wherein, subsequent to dispensing the encapsulation layer, the electrical connector extends through the encapsulation layer to provide an external package electrical connection to the PCB.

In addition to one or more of the features described above, or as an alternative, further embodiments could include dispensing the encapsulation layer on a first side of the package substrate such that an electrical connector extends from a second side of the package substrate that is opposite the first side and the electrical connector provides an external package electrical connection to the PCB.

In addition to one or more of the features described above, or as an alternative, further embodiments could include attaching an optically transparent window to a surface of the PDA, wherein the dispensing of the encapsulation layer physically contacts the optically transparent window with the encapsulation layer.

In addition to one or more of the features described above, or as an alternative, further embodiments could include electrically coupling the PCB to the ROIC using a plurality of bond wires.

In addition to one or more of the features described above, or as an alternative, further embodiments could include flip chip mounting the PDA to the ROIC and the electrically coupling of the PCB to the ROIC using the plurality of bond wires electrically couples the PCB to the PDA.

In addition to one or more of the features described above, or as an alternative, further embodiments could include placing the ROIC, the PDA and the PCB in their entireties within the recess in the package substrate.

In addition to one or more of the features described above, or as an alternative, further embodiments could include subsequent to the attaching of the PCB within the recess in the package substrate, the ROIC to the raised pedestal of the package substrate, and the PDA to the ROIC, the PCB surrounds the ROIC and the PDA through 360 degrees.

### BRIEF DESCRIPTION OF THE DRAWINGS

The accompanying drawings, which are incorporated in and constitute a part of this specification, illustrate embodiments of the present teachings and together with the description, serve to explain the principles of the disclosure. In the figures:

FIG. 1 is a perspective view of a substrate such as a metal substrate in accordance with an embodiment of the present teachings;

FIG. 2 is a perspective view of a windowed printed circuit board in accordance with an embodiment of the present teachings;

FIG. 3 is a perspective view of an image sensor assembly in accordance with an embodiment of the present teachings;

FIG. 4 is a cross sectional view of the FIG. 3 assembly;

FIG. 5 is a perspective depiction of the FIG. 3 image sensor assembly after an encapsulation process; and

FIG. 6 is a cross section depicting a conventional focal plane array.

It should be noted that some details of the FIGS. have been simplified and are drawn to facilitate understanding of the present teachings rather than to maintain strict structural accuracy, detail and scale.

### DETAILED DESCRIPTION OF THE INVENTION

Reference will now be made in detail to exemplary embodiments of the present teachings, examples of which are illustrated in the accompanying drawings. Wherever possible, the same reference numbers will be used throughout the drawings to refer to the same or like parts.

Achieving reliable electrical connections within a conventional device package becomes more challenging at decreasing device dimensions. A device such as that depicted in FIG. 6 includes many different material interfaces that may adversely affect device assembly and operation. There is a constant drive throughout the electronics industry to reduce the size, weight, and power of devices. The packaging of opto-electronic devices, such as that depicted in FIG. 6, may be constrained by three factors, including routing of electrical signals, the transfer of optical signals, and the dissipation of heat. This assembly methodology, however, creates multiple electrical, optical, and thermal interfaces that may result in a relatively large, heavy device with less than efficient power operation.

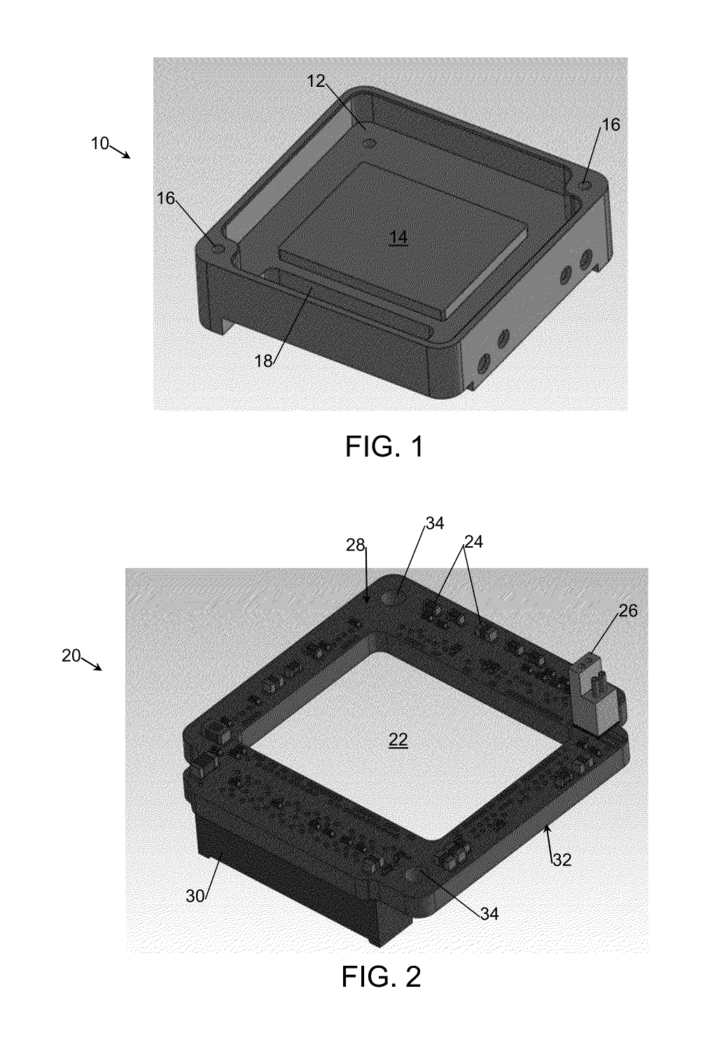

An embodiment of the present teachings may result in a device having a reduced size, weight, and improved packaging compared to some conventional devices. While an embodiment of the present teachings is described below with reference to FIGS. 1-4, it will be understood that various modifications to the depicted design are contemplated.

FIG. 1 depicts a device package substrate 10 which may be machined or molded. The package substrate 10 may be a conductor, either in part or in its entirety, for example a metal such as aluminum, or a dielectric, for example a ceramic or polymer. If formed from metal, the package substrate 10 may more efficiently function as a heat sink for internal device electronics assembled as described below. The package substrate 10 may include a recess 12 and a raised pedestal 14. The size of the pedestal 14 may be smaller than, or about the same size as, readout integrated circuit (ROIC) that will be attached thereto as described below. The package substrate 10 may also include holes 16, such as threaded holes, to facilitate connection of a printed circuit board (PCB) as described below, although other mechanical connection techniques and chemical connections, for example adhesives, are also contemplated. The package substrate 10 may also include one or more holes 18 sized to receive an electrical connector as described below.

The outline of the recess 12 of the package substrate 10 is sized to accommodate an organic or ceramic PCB 20, such as that depicted in FIG. 2. The PCB 20 includes an opening therethrough 22 that is sized to receive a ROIC as described below. The PCB 20 includes circuitry 24 thereon. The circuit design of the circuitry 24 may be generally as known in the art for operation of a focal plane array (FPA) device that includes a photodiode array (PDA) and a ROIC.

The PCB 20 may either include a first electrical connector 26 on an upper surface 28 of the PCB 20, a second electrical connector 30 on a lower surface 32 of the PCB 20 that extends through hole 18, or both a first electrical connector 26 and a second electrical connector 30. The electrical connectors 26, 30 will pass power, ground, and operational signals between the completed device and the apparatus into which the completed device is installed. The PCB 20 may further include through-holes 34 to facilitate connection to the package substrate 10.

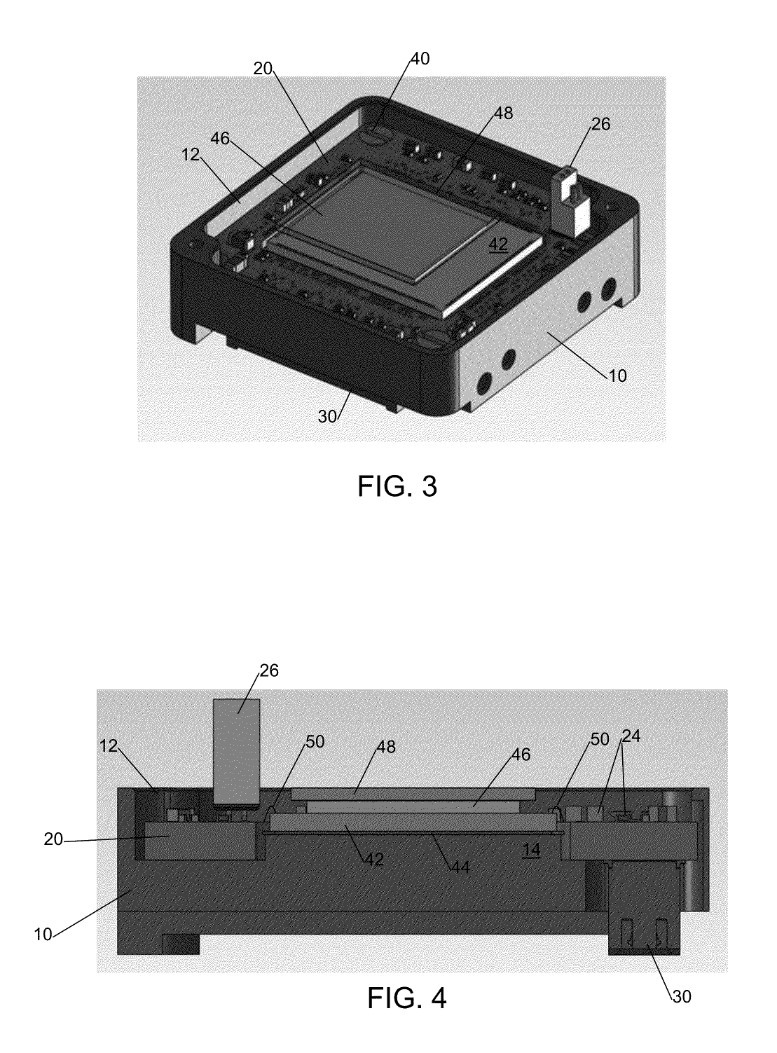

FIG. 3 is a perspective view, and FIG. 4 is a cross section, depicting the PCB 20 after connection to the package substrate 10 using a connection technique 40 such as screws or another connection technique. FIGS. 3 and 4 further depict a ROIC 42 attached to the pedestal 14, for example using a dielectric adhesive 44 (FIG. 4), and a PDA 46 attached to the ROIC 42. The PDA 46 may be flip chip mounted to the ROIC 42 so that circuitry on the PDA 46 is electrically coupled to circuitry on the ROIC 42 using, for example, ball grid array (BGA) connections (not depicted for simplicity) interposed between the PDA 46 and the ROIC 42. The device of FIGS. 3 and 4 may also include an optically transparent window or lid 48 attached to the upper surface of the PDA 46 using, for example, a glass frit or another optically transparent adhesive. As depicted in FIGS. 3 and 4, in this embodiment the PCB 20, the ROIC 42, and the PDA 46 are received within the recess 12 in the package body 10 in their entirety, although other embodiments are contemplated.

Circuitry on the upper surface of the ROIC 42 may be electrically coupled to the PCB 20 using, for example, bond wires 50. The bond wires 50 may also electrically couple circuitry on the PDA 46 to the circuitry on the PCB through the circuitry on the ROIC 42.

Thus in the depicted embodiment, upper and lower surfaces of the ROIC 42 and upper and lower surfaces of the PDA 46 are each at a lower level than an upper surface of the package substrate 10. After attachment to the PDA 46, an upper surface of the window 48 may about the same level as the upper surface of the package substrate 10. In other embodiments, the upper surface of the window 48 may be lower or higher than an upper surface of the package substrate 10. Additionally, the PCB 20 may surround both the ROIC 42 and the PDA 46 through 360 degrees as depicted in FIG. 3, although the PCB 20 may be designed to only partially surround the ROIC 42 and the PDA 46.

Assembly of the FIG. 3 device may be performed in any workable order. In an embodiment, the PCB 20 may be attached to the package substrate 10 prior or attachment of the ROIC 42 to the pedestal 14, or subsequently. The PDA 46 may be attached to the ROIC 42 prior to attaching the ROIC 42 to the pedestal 14, or subsequently.

At this point during assembly, the device of FIGS. 3 and 4 may be electrically tested for functionality. If the device fails, it may be easily disassembled and reworked for replacement of malfunctioning components.

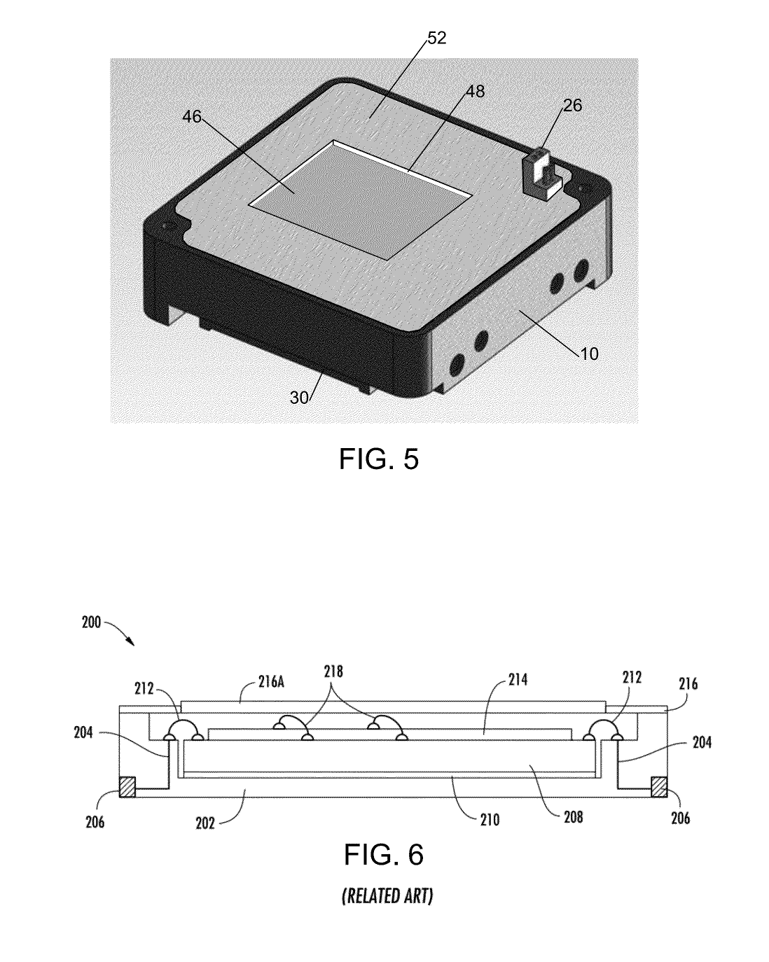

After completing the device of FIGS. 3 and 4, the device may be encapsulated by dispensing an encapsulation material within the remainder of the recess to fill the remainder of the recess 12 with a dielectric encapsulation layer, such as resin encapsulation layer 52 as depicted in FIG. 5. The encapsulation layer may environmentally seal at least a surface of the PCB 20, the ROIC 42 and the PDA 46 within the package substrate 10. The encapsulation layer 52 may physically contact the window 48.

After completion of the device as depicted in FIG. 5, external package electrical connection to internal device electronics such as the PDA 46, the ROIC 42, and the PCB 20 may be performed using either first connector 26, second connector 30, or both. As depicted, the first connector 26 is electrically coupled to the PCB 20 and extends from a first surface of the device and through the encapsulation layer 52. The first connector 26 thus provides an external package electrical connection to the PCB 20. The device of FIG. 5 may also include the second electrical connector 30 that is electrically coupled to the PCB 20 and extends from a second surface that is opposite the first surface of the device. The second electrical connector 30 thus provides an external package electrical connection to the PCB 20. A device may include either connector 26 or electrical connector 30, or both.

Notwithstanding that the numerical ranges and parameters setting forth the broad scope of the teachings are approximations, the numerical values set forth in the specific examples are reported as precisely as possible. Any numerical value, however, inherently contains certain errors necessarily resulting from the standard deviation found in their respective testing measurements. Moreover, all ranges disclosed herein are to be understood to encompass any and all sub-ranges subsumed therein. For example, a range of “less than 10” can include any and all sub-ranges between (and including) the minimum value of zero and the maximum value of 10, that is, any and all sub-ranges having a minimum value of equal to or greater than zero and a maximum value of equal to or less than 10, e.g., 1 to 5. In certain cases, the numerical values as stated for the parameter can take on negative values. In this case, the example value of range stated as “less than 10” can assume negative values, e.g. −1, −2, −3, −10, −20, −30, etc.

While the teachings have been illustrated with respect to one or more implementations, alterations and/or modifications can be made to the illustrated examples without departing from the spirit and scope of the appended claims. For example, it will be appreciated that while the process is described as a series of acts or events, the teachings are not limited by the ordering of such acts or events. Some acts may occur in different orders and/or concurrently with other acts or events apart from those described herein. Also, not all process stages may be required to implement a methodology in accordance with one or more aspects or embodiments of the present teachings. It will be appreciated that structural components and/or processing stages can be added or existing structural components and/or processing stages can be removed or modified. Further, one or more of the acts depicted herein may be carried out in one or more separate acts and/or phases. Furthermore, to the extent that the terms “including,” “includes,” “having,” “has,” “with,” or variants thereof are used in either the detailed description and the claims, such terms are intended to be inclusive in a manner similar to the term “comprising.” The term “at least one of” is used to mean one or more of the listed items can be selected. Further, in the discussion and claims herein, the term “on” used with respect to two materials, one “on” the other, means at least some contact between the materials, while “over” means the materials are in proximity, but possibly with one or more additional intervening materials such that contact is possible but not required. Neither “on” nor “over” implies any directionality as used herein. The term “conformal” describes a coating material in which angles of the underlying material are preserved by the conformal material. The term “about” indicates that the value listed may be somewhat altered, as long as the alteration does not result in nonconformance of the process or structure to the illustrated embodiment. Finally, “exemplary” indicates the description is used as an example, rather than implying that it is an ideal. Other embodiments of the present teachings will be apparent to those skilled in the art from consideration of the specification and practice of the disclosure herein. It is intended that the specification and examples be considered as exemplary only, with a true scope and spirit of the present teachings being indicated by the following claims.

Terms of relative position as used in this application are defined based on a plane parallel to the conventional plane or working surface of a workpiece, regardless of the orientation of the workpiece. The term “horizontal” or “lateral” as used in this application is defined as a plane parallel to the conventional plane or working surface of a workpiece, regardless of the orientation of the workpiece. The term “vertical” refers to a direction perpendicular to the horizontal. Terms such as “on,” “side” (as in “sidewall”), “higher,” “lower,” “over,” “top,” and “under” are defined with respect to the conventional plane or working surface being on the top surface of the workpiece, regardless of the orientation of the workpiece.

What is claimed is:

1. An image sensor, comprising:
a package substrate comprising a recess and a raised pedestal within the recess;
a read out integrated circuit (ROIC) physically attached to the raised pedestal;
a photodiode array (PDA) physically attached to the ROIC and electrically coupled therewith; and
a printed circuit board (PCB) within the recess in the package substrate, wherein the PCB has an opening therein and the raised pedestal at least partially extends through the opening in the PCB.

2. The image sensor of claim 1, further comprising an encapsulation layer that environmentally seals a surface of the PCB within the package substrate.

3. The image sensor of claim 2, further comprising an electrical connector electrically coupled to the PCB, wherein the electrical connector extends from the circuit board through the encapsulation layer to provide an external package electrical connection to the PCB.

4. The image sensor of claim 2, wherein the encapsulation layer is formed on a first side of the package substrate and the device further comprises an electrical connector electrically coupled to the PCB and extending from a second side of the package substrate that is opposite the first side to provide an external package electrical connection to the PCB.

5. The image sensor of claim 2, further comprising an optically transparent window attached to the PDA, wherein the encapsulation layer physically contacts the optically transparent window.

6. The image sensor of claim 1, further comprising a plurality of bond wires that electrically couple the PCB to the ROIC, wherein the PDA is flip chip mounted to the ROIC and the plurality of bond wires are electrically coupled to the PDA through the ROIC.

7. The image sensor of claim 1, wherein the ROIC, the PDA, and the PCB are received within the recess in the package substrate in their entirety.

8. A method for forming an image sensor, comprising:
attaching a printed circuit board (PCB) within a recess in a package substrate such that a raised pedestal within the recess of the package substrate at least partially extends through an opening within the PCB;
attaching a read out integrated circuit (ROIC) to the raised pedestal of the package substrate;
attaching a photodiode array (PDA) to the ROIC, wherein the PDA is electrically coupled to the ROIC; and
electrically coupling the ROIC to the PCB.

9. The method of claim 8, further comprising dispensing an encapsulation layer within the recess in the package substrate to environmentally seal a surface of the PCB within the package substrate.

10. The method of claim 9, further comprising physically contacting an electrical connector with the encapsulation layer during the dispensing of the encapsulation layer wherein, subsequent to dispensing the encapsulation layer, the electrical connector extends through the encapsulation layer to provide an external package electrical connection to the PCB.

11. The method of claim 9, further comprising dispensing the encapsulation layer on a first side of the package substrate such that an electrical connector extends from a second side of the package substrate that is opposite the first side and the electrical connector provides an external package electrical connection to the PCB.

12. The method of claim 9, further comprising attaching an optically transparent window to a surface of the PDA, wherein the dispensing of the encapsulation layer physically contacts the optically transparent window with the encapsulation layer.

13. The method of claim 8, further comprising:
flip chip mounting the PDA to the ROIC; and
electrically coupling the PCB to the PDA by using a plurality of bond wires to couple the PCB to the ROIC.

14. The method of claim 8, further comprising placing the ROIC, the PDA, and the PCB in their entireties within the recess in the package substrate.

15. The method of claim 14 wherein, subsequent to the attaching of the PCB within the recess in the package substrate, the ROIC to the raised pedestal of the package substrate, and the PDA to the ROIC, the PCB surrounds the ROIC and the PDA through 360 degrees.
